(19) United States
(12) Patent Application Publication
(10) Pub. No.: US 2013/0256822 A1
(43) Pub. Date: Oct. 3, 2013

(54) METHOD AND DEVICE WITH ENHANCED ION DOPING

(71) Applicants: Gang Chen, San Jose, CA (US); Duli Mao, Sunnyvale, CA (US); Hsin-Chih Tai, San Jose, CA (US); Howard Rhodes, San Martin, CA (US)

(72) Inventors: Gang Chen, San Jose, CA (US); Duli Mao, Sunnyvale, CA (US); Hsin-Chih Tai, San Jose, CA (US); Howard Rhodes, San Martin, CA (US)

(73) Assignee: OMNIVISION TECHNOLOGIES, INC., Santa Clara, CA (US)

(21) Appl. No.: 13/433,002

(22) Filed: Mar. 28, 2012

(51) Int. Cl. H01L 31/153; H01L 31/18

(52) U.S. Cl. 257/443; 438/73; 257/E31.102

(57) ABSTRACT

Techniques for providing a pixel cell which exhibits improved doping in a semiconductor substrate. In an embodiment, a first doping is performed through a backside of the semiconductor substrate. After the first doping, the semiconductor substrate is thinned to expose a front side which is opposite of the backside. In another embodiment, a second doping is performed through the exposed front side of the thinned semiconductor substrate to form at least part of a pixel cell structure.

### BACKGROUND OF THE INVENTION

1. Field of the Invention

This disclosure relates generally to image sensors, and in particular but not exclusively, relates to front side illumination CMOS image sensors.

2. Background Art

Image sensors have become ubiquitous. They are widely used in digital still cameras, cellular phones, security cameras, as well as medical, automobile, and other applications. The demands of higher performance have encouraged further miniaturization and integration of these image sensors. As a result, technology used to manufacture image sensors, for example, CMOS image sensors (“CIS”), has continued to advance at a great pace.

A front side illumination (FSI) image sensor device includes an imaging array that is fabricated on a front side of a semiconductor wafer, where light may be received at the semiconductor wafer from the same front side. By contrast, a backside illumination (BSI) image sensor includes an imaging array that is fabricated on the front side of a semiconductor wafer, but is to receive light through an opposite back side of such a wafer. To detect light received via the backside, the silicon wafer of a BSI pixel array may be relatively thin, as compared to that of a FSI pixel array.

Typically, a pixel array is comprised of pixel cells which include one or more doped regions of a semiconductor substrate. Formation of such doped regions has previously been achieved by performing diffusion and/or implantation of some dopant through the front side of the semiconductor substrate. The depth of such diffusion or implantation, as measured from the front side of the semiconductor substrate, has typically been limited to extending no more than approximately 2 μm deep into the substrate. To date, extending the depth of such doped regions—e.g. with higher-power ion implantation—has been limited by other constraints of pixel cell fabrication, such as the need to concurrently implement effective masking to form and/or protect pixel cell structures during doping.

The limited depth of such doped regions affects quantum efficiency and other measures of pixel cell performance. This is particularly the case, for example, with regard to the operation of a pixel cell to detect for light having a long wavelength—e.g. as compared to the wavelength of visible light. For example, infrared radiation is absorbed much deeper in pixel cell silicon than is visible light. The insufficient depth of photodiode regions formed according to conventional doping techniques results in a substantial amount of infrared light passing through conventional pixel cells' photodiodes undetected.

### BRIEF DESCRIPTION OF THE DRAWINGS

The various embodiments of the present invention are illustrated by way of example, and not by way of limitation, in the figures of the accompanying drawings and in which:

FIGS. 1A through 1F are cross-sectional diagrams illustrating elements of a pixel cell fabrication process according to an embodiment.

FIG. 2 is a block diagram illustrating elements of a method for fabricating a pixel cell according to an embodiment.

FIG. 3 is a block diagram illustrating elements of a pixel cell including one or more doped regions according to an embodiment.

FIG. 4 is a circuit diagram illustrating elements of pixel circuitry of two pixels in a front side illumination image sensor, in accordance with an embodiment.

FIG. 5 is a block diagram illustrating elements of a front side illumination image sensor according to an embodiment.

FIG. 6 is a graph of a dopant concentration profile of a pixel cell according to an embodiment.

### DETAILED DESCRIPTION

Embodiments of a process, apparatus and system for improved doping of a pixel cell for an imaging sensor are described herein. In an embodiment, a first doping of a semiconductor substrate for a pixel cell is performed through a backside of the semiconductor substrate. After the first doping, the semiconductor substrate may be thinned to expose another side of the substrate—e.g. where the newly-exposed side is to serve as a front side opposite of the backside. After the front side is exposed by such thinning, a second doping of the semiconductor substrate may be performed through the front side—e.g. to form a second part of a pixel cell structure which also includes a doped region formed by the first doping.

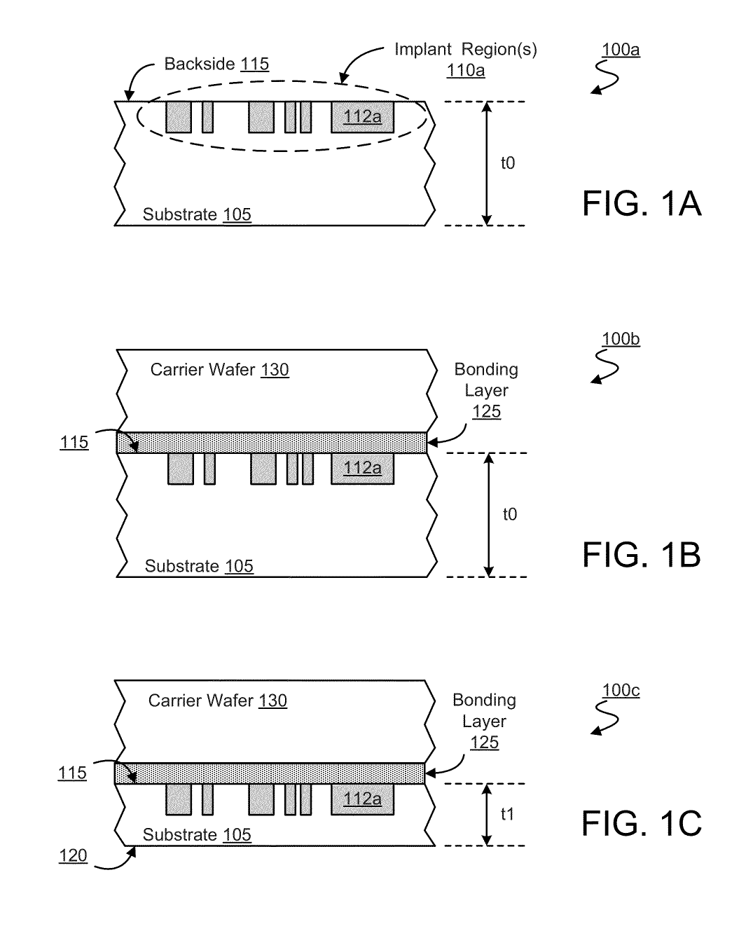

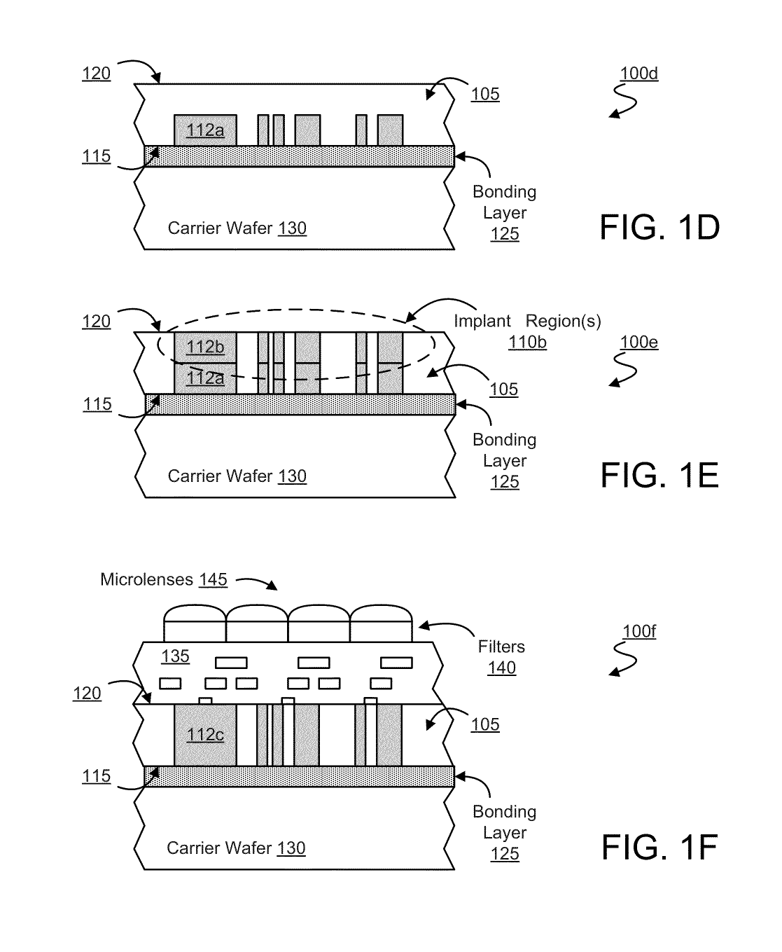

FIG. 1A provides a high-level view of elements in an assembly 100a for fabrication of a pixel array according to an embodiment. Such a pixel array may operate as a front side illumination (FSI) image sensor, for example, although certain embodiments are not limited in this regard.

In an embodiment, assembly 100a includes a substrate 105 comprising any of a variety of combinations of one or more known semiconductor materials to serve as a substrate for a pixel array. By way of illustration and not limitation, substrate 105 may include one or more of a p-type semiconductor, an n-type semiconductor, an un-doped (i.e., neither p-type nor n-type) semiconductor, and/or some combination thereof. In one embodiment, substrate 105 includes a p-type epitaxial silicon substrate. Substrate 105 may include a side, represented by an illustrative backside 115, which is to serve as a backside of substrate 105 with respect to a path along which light is to be received by substrate 105. For example, a FSI pixel array may be fabricated from assembly 100a, where light received by such a FSI pixel array during operation thereof is to enter some front side (not shown) of substrate 105 which is an opposite side with respect to backside 115. In an alternate embodiment, a BSI pixel array may be fabricated from assembly 100a, where light received by such a BSI pixel array is to enter substrate 105 via backside 115.

In an embodiment, substrate 105 includes one or more doped regions each having a respective doping which differs from that of substrate 105 generally. Such one or more doped regions of substrate 105 may, for example, include one or more diffusion regions formed by a diffusion process and/or one or more implant regions formed by an implant process. To avoid obscuring certain features of various embodiments, such dopant regions are discussed herein with respect to one or more implant regions and/or implant processes to form such one or more implant regions. However, such discussion may be extended to additionally or alternatively apply to one or more diffusion regions and/or diffusion processes to achieve such one or more diffusion regions, in different embodiments.

By way of illustration and not limitation, one or assembly 100a may include one or more implant regions 110a formed in substrate 105. Fabrication of assembly 100a may include performing one or more implant processes to variously implant dopants through backside 115 into substrate 105—e.g. for forming one or more implant regions 110a. The number and respective shapes and sizes of one or more implant regions 110a are merely illustrative of one embodiment, and are not limiting on certain other embodiments. For example, assembly 100a may include any of a variety of additional or alternative implant regions formed by implantation through backside 115.

Features of various embodiments are discussed herein with respect to an illustrative first implant region 112a of one or more implant regions 110a. However, such discussion may be extended to variously apply to one or more additional or alternative implant regions formed by implanting dopants through backside 115 into substrate 105. In an embodiment, first implant region 112a is to eventually serve as at least part of some structure in a pixel cell, or structure between pixel cells, of a pixel array formed from assembly 100a. By way of illustration and not limitation, first implant region 112a may eventually serve as at least part of circuit element such as a photodiode of a pixel cell—e.g. where substrate 105 is a p-type silicon substrate and first implant region 112a is at least part of an n-type doped photodiode region in substrate 105. In another embodiment, first implant region 112a may eventually serve as at least part of a diffusion well—e.g. a p-well—in a pixel array formed from assembly 100a. In still another embodiment, first implant region 112a may eventually serve as part of an isolation structure to electrically isolate different circuit elements of a pixel cell from one another and/or to electrically isolate different pixel cells from one another. However, certain embodiments are not limited with respect to the particular type of pixel cell structure which might eventually include first implant region 112a. In certain embodiments, one or more pixel cell structures may be subsequently formed within first implant region 112a as part of fabrication of a finally formed pixel cell.

Forming first implant region 112a may, for example, include implanting a dopant through an opening in a photoresist mask layer (not shown) which is disposed on the surface of backside 115. Such an opening in the photoresist mask layer may expose a portion of the surface of backside 115 corresponding to a desired shape for first implant region 112a. For example, the photoresist mask may limit the extension of first implant region 112a in some or all directions along the surface of backside 105. In certain embodiments, conventional techniques for applying a photoresist material to a semiconductor substrate are adapted for formation of such a photoresist mask layer on backside 115. By way of illustration and not limitation, the photoresist layer for forming first implant region 112a may be at least partially based upon an inverse of a mask layer which is used for forming a conventional pixel cell structure by implantation through a front side of a semiconductor substrate.

At some point during fabrication of assembly 100a, substrate 105 may have some thickness t0—e.g. as measured from the surface of backside 115 to some other side which is opposite to backside 115. For example, substrate 105 may have thickness t0 prior to and/or after implant processing which forms one or more implant regions 110a. By way of illustration and not limitation, thickness t0 may be 725 μm, as is typical of some 200 mm diameter wafers, or 775 μm, as is typical of some 300 mm diameter wafers. Certain embodiments are not limited with respect to the particular thickness t0 of substrate 105.

FIG. 1B provides a high-level view of elements in an assembly 100b for fabrication of a pixel array according to an embodiment. Assembly 100b may, for example, be generated from additional processing, subsequent to that for forming assembly 100a.

In an embodiment, after one or more implant regions 110a have been implanted through the backside 115, substrate 105 may be prepared for additional implantation processing—e.g. to implant dopants through a side of substrate 105 other than backside 115. Preparing for such additional processing may include attaching a carrier wafer 130 (also referred to as a handling wafer) directly or indirectly onto substrate 105.

For example, carrier wafer 130 may be attached to backside 115 of substrate 105 to provide physical support—e.g. to buffer and/or absorb stress—so that substrate 105 and/or structures therein are not damaged by forces applied to assembly 100b during subsequent fabrication processing. In certain embodiments, carrier wafer 130 may be made up of one or more materials including, but not limited to, a dielectric material, a semiconductor material, a metal or other conductor, and/or the like. In an embodiment where assembly 100b is for fabricating a FSI pixel array, carrier wafer 130 may remain permanently attached to substrate 105 if necessary, but in embodiments where assembly 100b is for fabricating a BSI pixel array, carrier wafer 130 may be removed after manufacture of the BSI pixel array is complete.

In an embodiment, carrier wafer 130 is attached via a bonding layer 125 to backside 115—e.g. where bonding layer 125 includes a layer of oxide material. Such an oxide material may, for example, be deposited onto backside 115 prior to positioning carrier wafer 130 onto bonding layer 125. Additionally or alternatively, an oxide material may be applied to carrier wafer 130 for adhesion to backside 115 and/or any oxide material deposited thereon.

Bonding layer 125 may be composed of multiple component layers (not shown), although certain embodiments are not limited in this regard. For example, bonding layer 125 may include a component layer of polysilicon, for example, to act as an electrode for use in later fabrication processing. Such a polysilicon layer of bonding layer 125 may provide for the application of a voltage to such polysilicon—e.g. to affect the behavior of carriers in first implant region 112a. Bonding layer 125 may have additional functions such as to act as an infrared absorbing layer to prevent reflections of infrared radiation or an infrared reflecting layer to reflect infrared radiation back into the photosensitive region for additional signal collection.

FIG. 1C provides a high-level view of elements in an assembly 100c for fabrication of a pixel array according to an embodiment. Assembly 100c may, for example, be generated from additional processing, subsequent to that for forming assembly 100b.

In an embodiment, after adhesion of carrier wafer 130 onto backside 115 of substrate 105, the thickness t0 of substrate 105 may reduced to a smaller thickness t1 by removing material from substrate 105. Thinning substrate 105 from its initial thickness t0 to a smaller thickness t1 may form—e.g. expose—another side, represented by an illustrative front side 115, which is to serve as a front side of substrate 105 with respect to a path along which light is to be received by substrate 105 during operation of the pixel array. Thinning substrate 105 may allow for additional ion implanting—e.g. to extend a depth of doping beyond the depth of some or all of the one or more implant regions 100a.

Reducing the thickness of substrate 105 from t0 to t1 may be accomplished by removing substrate material using mechanical techniques such as grinding or chemical mechanical polishing (CMP). In another embodiment, such material may be removed to expose front side 120 using other techniques such as wet or dry chemical etching. In still other embodiments, such material may be removed using a combination of mechanical and chemical techniques or a combination of different chemical techniques.

FIG. 1D provides a high-level view of elements in an assembly 100d for fabrication of a pixel array according to an embodiment. Assembly 100d may, for example, be a result of changing an orientation of—e.g. inverting—assembly 100c in preparation for one or more subsequent fabrication processes. In an embodiment, such orienting of assembly 100d may face front side 120 in an upward direction to facilitate an implantation, diffusion or other ion doping process.

FIG. 1E provides a high-level view of elements in an assembly 100e for fabrication of a pixel array according to an embodiment. Assembly 100e may, for example, be generated from additional processing, subsequent to that for forming assembly 100d.

In an embodiment, assembly 100e includes one or more implant regions 110b. Fabrication of assembly 100e may include performing one or more implant processes to variously implant dopants through front side 120 into substrate 105—e.g. for forming one or more implant regions 110b. The number and respective shapes, sizes, etc. of one or more implant regions 110b are merely illustrative of one embodiment, and are not limiting on certain other embodiments. For example, assembly 100e may include any of a variety of additional or alternative implant regions formed by implantation through front side 120.

In an embodiment, some or all of the one or more implant regions 110b are each aligned with a respective one of the one or more implant regions 110a. By way of illustration and not limitation, an infrared aligner may detect at a sensor light which an infrared lamp sends through the partially-implanted substrate 105 of assembly 100d. Based on sensing such infrared light, the infrared aligner may determine the position of one or more implant regions 110a in substrate 105. Based on the determined position of one or more implant regions 110a, the aligner may determine how to position one or more implant regions 110b. For example, the aligner may determine from the position of one or more implant regions 110a how a photoresist mask layer (not shown) is to be formed on front side 120 for formation of one or more implant regions 110a.

Features of various embodiments are discussed herein with respect to an illustrative second implant region 112b of one or more implant regions 110b. However, such discussion may be extended to variously apply to one or more additional or alternative implant regions formed by implanting dopants through front side 120 into substrate 105. In an embodiment, second implant region 112b is to eventually serve as at least part of some structure in a pixel cell, or structure between pixel cells, of a pixel array formed from assembly 100e. By way of illustration and not limitation, second implant region 112b may eventually serve as at least part of a photodiode or other circuit element, a diffusion well, an isolation structure and/or the like. Such a pixel structure may, for example, include both first implant region 112a and second implant region 112b—e.g. where first implant region 112a and second implant region 112b are contiguous with one another. However, certain embodiments are not limited with respect to the particular type of pixel cell structure which might eventually include second implant region 112b. In certain embodiments, one or more pixel cell structures may be subsequently formed within second implant region 112b as part of fabrication of a finally formed pixel cell.

Implantation of second implant region 112b through front side 120 into substrate 105 may, for example, include performing an ion implantation through an opening in a mask layer (not shown) which is disposed on the surface of front side 120. Such a mask may, for example, limit the extension of second implant region 112b in some or all directions along the surface of front side 120—e.g. for shaping at least part of a final pixel structure which includes second implant region 112b. In an embodiment, masking and/or doping techniques may be applied to define one or more edges of second implant region 112b which each align with an respective edge of first implant region 112a. Alternatively or in addition, fabrication of second implant region 112b may result in second implant region 112b being contiguous with first implant region 112a.

FIG. 1F provides a high-level view of elements of a pixel array 100f according to an embodiment. Pixel array 100f may, for example, be generated from additional processing, subsequent to that for forming assembly 100e.

In an embodiment, one or more implant regions 110a and one or more implant regions 110b may form circuit elements or other pixel cell structures in pixel array 100f. By way of illustration and not limitation, first implant region 112a and second implant region 112b may form some or all of a pixel cell structure 112c. Pixel cell structure 112c may serve as at least part of a circuit element of a pixel cell or as a structure for aiding operation of such a pixel cell circuit element. For example, pixel cell structure 112c may include a photodiode, a diffusion well, an isolation structure and/or the like.

Fabrication of pixel array 100f may include forming one or more additional pixel cell structures in and/or on substrate 105 of assembly 100e. By way of illustration and not limitation, fabrication of pixel array 100f may include forming one or more metal layers, represented by an illustrative metal stack 135. In an embodiment, front side 120 of substrate 105 faces toward the one or more metal layers of metal stack 135. Fabrication of pixel array 100f may further include forming filters 140 and/or microlenses 145 over metal stack 135, although certain embodiments are not limited in this regard. The formation of some or all of metal stack 135, filters 140 and microlenses 145 may be according to conventional pixel cell fabrication techniques. Certain embodiments are not limited with respect to the particular type, number, variety, etc. of additional pixel cell structures—e.g. microlenses, filters, metal layers and/or other structures—which may be added to an assembly such as assembly 100e.

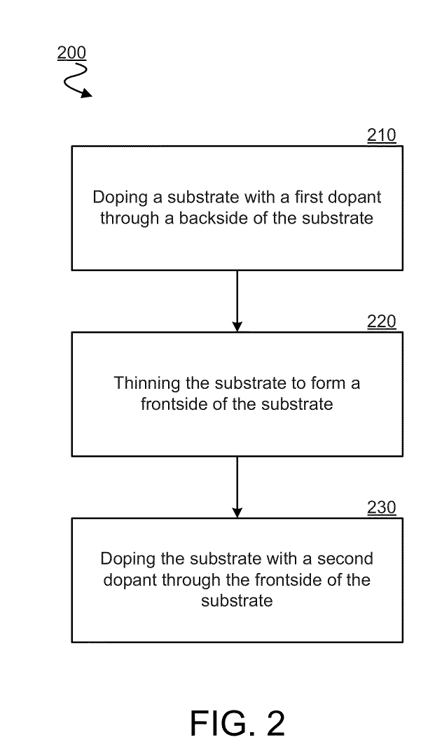

FIG. 2 illustrates elements of a method 200 for fabricating a pixel cell according to an embodiment. Method 200 may, for example, fabricate structures having some of all of the features discussed with respect to FIGS. 1A-1F.

Method 200 may include, at 210, doping a substrate with a first dopant through a backside of the substrate. The doping with the first dopant may, for example, form at least part of a pixel structure of a front side illumination pixel cell. In an embodiment, the first dopant includes a p-type dopant such as boron, aluminum, gallium, indium, and/or thallium, although certain embodiments are not limited in this regard. In an alternate embodiment, the first dopant includes an n-type dopant such as phosphorus, antimony and/or the like. Certain embodiments are not limited with respect to the doping of a particular type (e.g. n-type or p-type) of dopant into a particular type (e.g. n-type or p-type) of substrate region.

After the doping at 210, method 200 may further include performing, at 220, a thinning of the substrate to form a front side of the substrate. Thinning the substrate may, for example, include one or more processes including, but not limited to, grinding, chemical mechanical polishing (CMP), wet chemical etching, dry chemical etching and/or the like. In certain embodiments, a carrier layer is bonded to the backside of the substrate after the doping at 210—e.g. prior to the thinning at 220. Such a carrier layer may be bonded to protect the substrate from stresses which are imposed by the substrate thinning at 220 and/or by later orienting or processing of the thinned substrate.

After thinning the substrate, method 200 may include, at 230, doping the substrate with a second dopant through the front side of the substrate. In an embodiment, the second dopant is of the same dopant type as that of the first dopant—e.g. where both the first and second dopants are both p-type. In an embodiment, the doping with the first dopant forms a first doped region in the substrate, wherein the doping with the second dopant forms a second doped region in the substrate which adjoins the second doped region.

A circuit element or other structure of a pixel cell may be comprised of the first doped region and the second doped region. Such a circuit element or structure may itself be considered a doped region—e.g. where the first doped region and the second doped region each are sub-regions of such a doped region. For example, the first doped region and the adjoining second doped region may together serve as a photodiode, a diffusion well, an isolation structure and/or the like. Doping from both the front side and the backside of the substrate may allow the formation of a contiguous, aggregate doped region having twice the thickness of regions which are doped according to conventional techniques. For example, a doped region may extend beyond the typical limits of ˜2 micron—e.g. where a doped region has a depth (also referred to herein as thickness) of at least 3 microns, in one embodiment.

Doping the substrate with the second dopant at 230 may include performing an alignment to assure that one or more doped regions created by the doping at 230 are correctly positioned relative to one or more doped regions created by the doping at 210. By way of illustration and not limitation, an infrared aligner may be used to determine the position of one or more doped regions already in the substrate. Based on the determined position of the previously doped regions, the aligner may determine how to position on the front side of the substrate a photoresist mask layer for masking the doping with the second dopant.

After doping with the second dopant at 230, the substrate—e.g. along with any carrier layer bonded to the backside of the substrate—may be provided for additional processing. For example, method 200 may further include one or more additional operations (not shown) to fabricate any of a variety of additional pixel cell structures in and/or on the substrate. Additionally or alternatively, a metal layer may be formed directly or indirectly on the front side of the substrate—e.g. the metal layer including one or more metal traces for operation of the pixel array. Additionally or alternatively, one or more color filters, microlenses, and/or other structures may be formed directly or indirectly on such a metal layer. The formation of such additional pixel cell structures may be according to any of a variety of conventional techniques, and may not be limiting on certain embodiments.

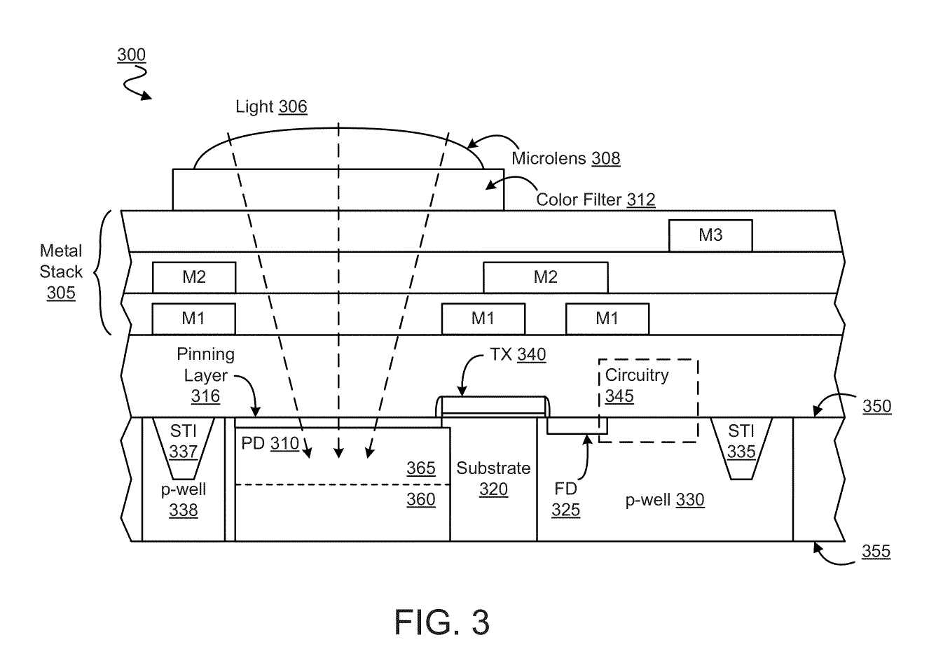

FIG. 3 a cross-sectional view of elements in a pixel cell 300 of a front side illumination (“FSI”) CMOS image sensor (“CIS”) according to an embodiment. Pixel cell 300 may be fabricated according to a process including some or all of the features of method 200, for example.

In an embodiment, pixel cell 300 includes a substrate 320 having a front side 350 and a backside 355, where various structures of pixel cell 300 are formed in or on front side 350, and where a metal stack 305 is formed directly or indirectly on front side 350. Metal stack 305 may include one or more metal layers, represented by the illustrative metal layers M1, M2 and M3, which are patterned to allow light (indicated by dashed arrows 306) incident on pixel cell 300 to reach a photodiode region PD 310—e.g. via a microlens 308. In one embodiment, PD 310 is configured to be primarily responsive to infrared light. Pixel cell 300 may further include a color filter 312 disposed under microlens 308, although certain embodiments are not limited in this regard.

One or more circuit elements or other structures of pixel cell 300 may be variously formed in and/or on substrate 320. By way of illustration and not limitation, substrate 320 may include a p-type epitaxial layer or other suitable semiconductor material in which is formed PD 310, a p-type pinning layer 316 over PD 310, a floating diffusion (“FD”) region 325 disposed in a p-well 330, and a shallow trench isolation (“STI”) 335. A transfer transistor TX 340 (not fully illustrated) may be disposed between PD 310 and FD region 325, for use in transferring a signal output by PD 310 to FD region 325. The pixel array may include one or more additional structures—e.g. a STI 337 in a p-well 338—to electrically isolate pixel cell 300 from an adjoining pixel cell (not shown).

In an embodiment, pixel cell 300 may operate as follows. During an integration period (also referred to as an exposure or accumulation period), light 306 is incident on PD 310. PD 310 generates an electrical charge in response to the incident light 306. The electrical charge is held in PD 310. At this stage, TX 340 may be turned off—e.g. resistant to electron flow between PD 310 and FD region 325—due to a bias voltage on the gate of TX 340 being less than a threshold voltage for TX 340. After the integration period, TX 340 may be turned on to read out a signal from PD 310 corresponding to the generated charge. For example, a positive bias voltage may be applied to the gate of TX 340 to aid the transfer of charge from PD 310 to FD region 325. After the electrical signal in PD 310 has been transferred to FD region 325, TX 340 may be turned off in anticipation of a next integration period. Based on the charge transferred from PD 310 to FD 325, additional circuitry 345 of pixel cell 300 may operate to generate an analog signal which pixel cell 300 is to output via a trace in metal stack 305.

In an embodiment, a given doped region in substrate 320—e.g. PD 310—includes a first sub-region and a second sub-region (such as first doped sub-region 360 and second doped sub-region 365, respectively) which may be adjacent to one another. The first sub-region 360 may, for example, be formed at least in part by a doping which is performed through a backside 355—e.g. per operation 210. Additionally or alternatively, the second sub-region 365 may be formed at least in part by a doping through frontside 350—e.g. per operation 220. Such two-sided doping may provide for PD 310 to have a longer extension into substrate 320, as compared to the depth of a photodiode region formed according to conventional (e.g. one-sided) doping techniques. The addition extension of PD 310 deep into substrate 320 may improve the sensitivity—e.g. infrared sensitivity—of pixel cell 300.

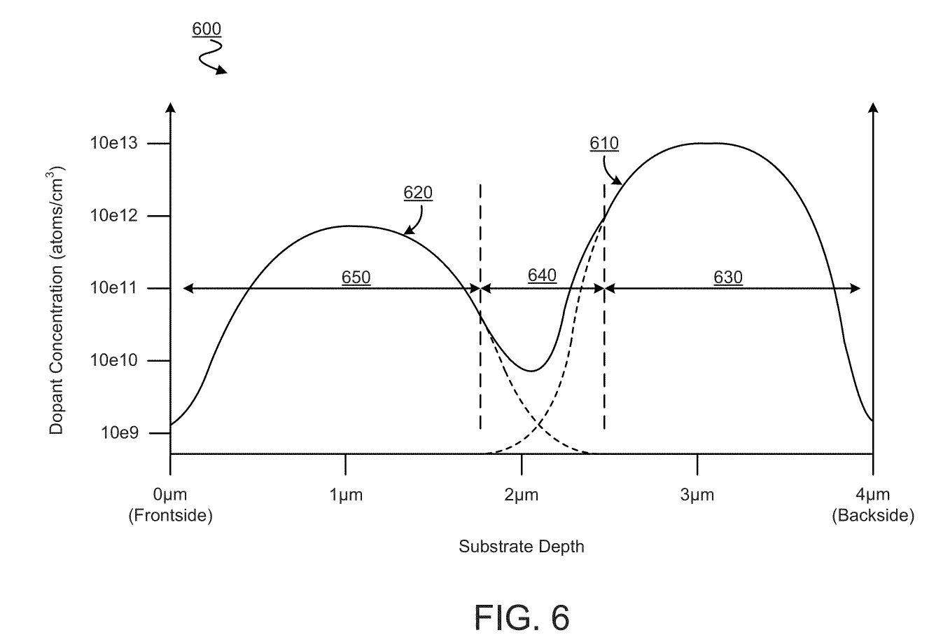

PD 310, or any other doped region, may be characterized by a particular dopant concentration profile. As used herein, “dopant concentration profile” refers to a set of various levels of concentration of a dopant, the various levels for different respective locations in the doped region—e.g. where the locations are along a line extending between a backside of a substrate and a frontside of the substrate. FIG. 6 is an illustrative graph of one type of dopant concentration profile 600 of doped region in a pixel cell according to an embodiment. However, a doped region may have any of a variety of alternative dopant concentration profiles, according to different embodiments. The particular concentration values shown in FIG. 6 are merely illustrative, and not limiting on various embodiments.

Features of dopant concentration profile 600 are discussed herein with reference to pixel cell 300. However, such discussion may be extended to variously apply to any of a variety of other dopant concentration profiles and/or any of a variety of pixel cells according to different embodiments. In an embodiment, the doping through the backside 355 to form the first sub-region may contribute a first concentration component 610 to the dopant concentration profile 600 for the entire doped region. The first concentration component 610 may include its own respective dopants which exhibit a concentration gradient according to (e.g. conforms to) a particular curve such as a first log-normal curve. Additionally or alternatively, the doping through the frontside 350 of substrate 320 to form the second sub-region may contribute a second concentration component 620 to the dopant concentration profile 600 for the entire doped region. The second concentration component 620 may include its own respective dopants which exhibit a concentration gradient according to another curve—e.g. according to a second log-normal curve. To aid in illustrating features of various embodiments, concentration levels of dopant concentration profile 600 are shown in a logarithmic scale. Either or both of concentration components 610, 620 may variously exhibit one or more different log-normal distribution characteristics (e.g. skew, mean, standard deviation, and/or the like), according to different embodiments.

The respective concentration curves for the concentration components 610, 620 may be offset from one another in substrate 320—e.g. since they correspond to doping through opposite respective sides of substrate 320. Consequently, the dopant concentration profile 600 for the overall doped region may include a first portion 630 in which the first concentration component 610 predominates, and where the second concentration component 620 is negligible or even undetectable. Such a first portion 630 may, for example, be located proximate to backside 355, through which doping was performed to form the first sub-region. Alternatively or in addition, the dopant concentration profile 600 for the overall doped region may include a second portion 650 in which the second concentration component 620 predominates, and where the first concentration component 610 is negligible or even undetectable. Such a second portion 650 may, for example, be located proximate to the frontside 350, through which doping was performed to form the second sub-region.

Accordingly, various embodiments include or otherwise provide a pixel cell comprising a doped region having a dopant concentration profile 600 including a first portion 630 exhibiting a first concentration gradient according to a first log-normal curve and a second portion 650 exhibiting a second concentration gradient according to a second log-normal curve. The first portion 630 and second portion 650 may correspond, respectively, to a first sub-region and a second sub-region adjoining the first sub-region. In an embodiment, a third portion 640 of the dopant concentration profile 600 is located between the first portion 630 and the second portion 650. The third portion 640 may exhibit a concentration gradient which is not according to only the first log-normal curve and which is not according to only the second log-normal curve. By way of illustration and not limitation, the concentration gradient of the third portion 640 may be according to a sum of curves which includes the first log-normal curve and the second log-normal curve. In an embodiment, the dopant concentration profile 600 includes two or more local concentration maxima—e.g. where one of the local maxima is substantially equal to a maxima of the first log-normal curve and/or where another of the local maxima is substantially equal to a maxima of the second log-normal curve.

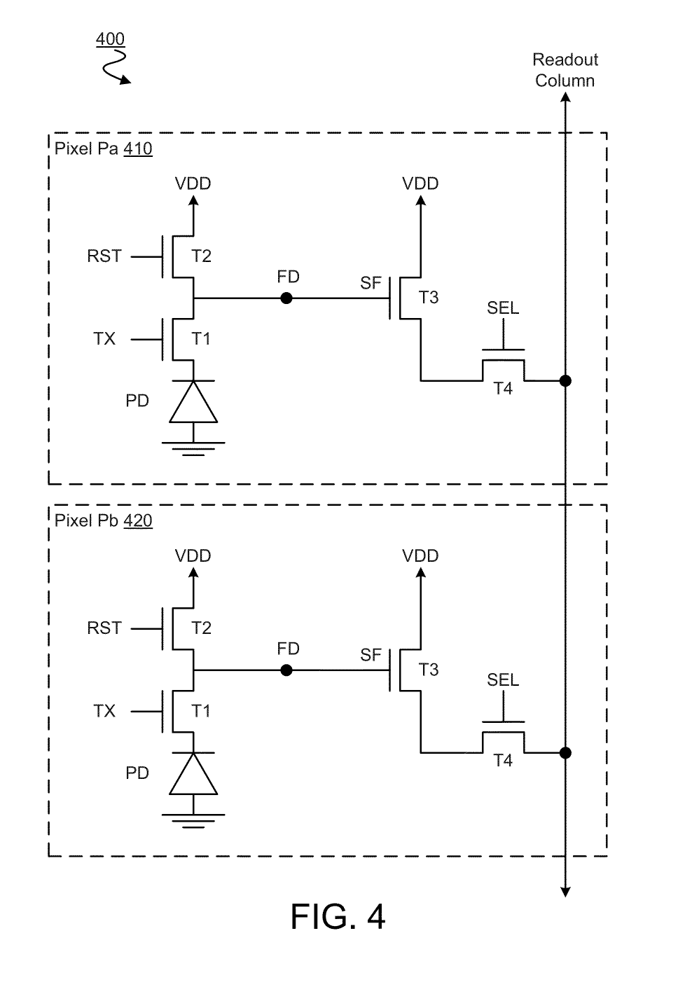

FIG. 4 is a circuit diagram illustrating pixel circuitry 400 of two four-transistor (“4T”) pixels Pa 410 and Pb 420 within a FSI imaging array, in accordance with an embodiment of the invention. Pixel circuitry 400 is one possible pixel circuitry architecture for implementing pixels formed according to the techniques discussed with respect to FIGS. 1A-1F. However, it should be appreciated that such embodiments are not limited to 4T pixel architectures; rather, one of ordinary skill in the art having the benefit of the instant disclosure will understand that the present teachings are also applicable to 3T designs, 5T designs, and various other pixel architectures. In FIG. 4, pixels Pa 410 and Pb 420 are arranged in two rows and one column. In the illustrated embodiment, each of pixels Pa 410 and Pb 420 includes a photodiode PD, a transfer transistor T1, a reset transistor T2, a source-follower (“SF”) transistor T3, and a select transistor T4. In one embodiment, PD is configured to be primarily responsive to infrared light. During operation, transfer transistor T1 may receive a transfer signal TX, which transfers the charge accumulated in photodiode PD to a floating diffusion node FD. In one embodiment, floating diffusion node FD may be coupled to a storage capacitor for temporarily storing image charges. Reset transistor T2 may be coupled between a power rail VDD and the floating diffusion node FD to reset (e.g., discharge or charge the FD to a preset voltage) under control of a reset signal RST. The floating diffusion node FD may be coupled to control the gate of SF transistor T3. SF transistor T3 may be coupled between the power rail VDD and select transistor T4. SF transistor T3 may operate as a source-follower providing a high impedance output from the pixel. Finally, select transistor T4 may selectively couple the output of pixel circuitry 400 to the readout column line under control of a select signal SEL. In one embodiment, the TX signal, the RST signal, and the SEL signal are variously generated by control circuitry (not shown).

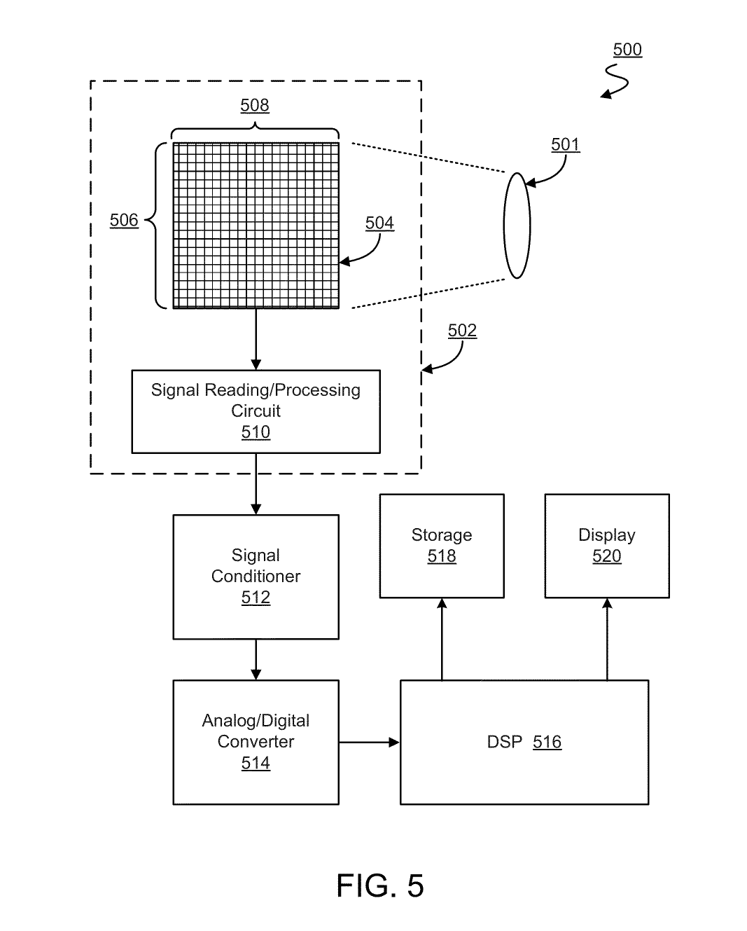

FIG. 5 illustrates elements of an imaging system 500 according to an embodiment. Imaging system 500 may include optics 501, an image sensor 502 to receive light via optics 501, and circuitry to receive and process signals generated by image sensor 502 based on such received light. In imaging system 500, circuitry to receive and process signals generated by image sensor 502 is represented as including one or more of an illustrative signal conditioner 512, analog-to-digital converted 514, digital signal processor 516, storage 518 and display 520. However, any of a variety of combinations of one or more additional or alternative components to receive and process such signals may be provided, according to different embodiments.

Optics 501, which may include refractive, diffractive or reflective optics or combinations thereof, may be coupled to image sensor 502 to focus an image onto the pixels in pixel array 504 of the image sensor. Pixel array 504 may capture the image and the remainder of imaging system 500 may process resulting pixel data for representing the image.

Image sensor 502 may, for example, comprise a pixel array 504 and a signal reading and processing circuit 510. Pixel array 504 may include a plurality of pixels arranged in rows 506 and columns 508. During operation of pixel array 504 to capture an image, some or all of the pixels in pixel array 504 may capture incident light (i.e., photons) during a certain exposure period and convert the collected photons into an electrical charge. The respective electrical charges generated by such pixels may each be read out as a corresponding analog signal, where a characteristic of such an analog signal—e.g. its charge, voltage or current—is representative of the intensity of light that was incident on the pixel during the exposure period.

Illustrated pixel array 504 is regularly shaped, but in other embodiments the array may have a regular or irregular arrangement different than shown and may include more or less pixels, rows, and columns than shown. Alternatively or in addition, pixel array 504 may be a color image sensor—e.g. including red, green, and blue pixels designed to capture images in the visible portion of the spectrum—a black-and-white image sensor and/or an image sensor designed to capture images in the invisible portion of the spectrum, such as infra-red or ultraviolet.

Image sensor 502 may include signal reading and processing circuit 510 having logic to methodically read analog signals from some or all pixels of pixel array 504 and, in an embodiment, to further provide processing—e.g. to filter such signals, correct for defective pixels, provide white balancing and/or the like. In an embodiment, circuit 510 may perform only some signal processing—e.g. where other signal processing is performed by one or more other components such as signal conditioner 512 or DSP 516. Although shown in the drawing as an element separate from pixel array 504, in some embodiments reading and processing circuit 510 may be integrated with pixel array 504—e.g. on the same silicon substrate and/or otherwise comprising circuit logic embedded within pixel array 504. In other embodiments, reading and processing circuit 510 may be an element not only external to pixel array 504, but also external to image sensor 502.

Signal conditioner 512 may be coupled to image sensor 502 to receive and condition analog signals from pixel array 504 and reading and processing circuit 510. In different embodiments, signal conditioner 512 may include various components for conditioning analog signals. Examples of components that may be found in signal conditioner 512 include filters, amplifiers, offset circuits, automatic gain control, etc. Analog-to-digital converter (ADC) 514 may be coupled to signal conditioner 512 to receive conditioned analog signals corresponding to each pixel in pixel array 504 from signal conditioner 512 and convert these analog signals into digital values.

Digital signal processor (DSP) 516 may be coupled to analog-to-digital converter 514 to receive digitized pixel data from ADC 514 and process the digital data to produce a final digital image. DSP 516 may, for example, include a processor and an internal memory in which it may store and retrieve data. After the image is processed by DSP 516, it may be output to one or both of a storage unit 518 such as a flash memory or an optical or magnetic storage unit and a display unit 520 such as an LCD screen.

Techniques and architectures for pixel cell fabrication and operation are described herein. In the above description, for purposes of explanation, numerous specific details are set forth in order to provide a thorough understanding of certain embodiments. It will be apparent, however, to one skilled in the art that certain embodiments can be practiced without these specific details. In other instances, structures and devices are shown in block diagram form in order to avoid obscuring the description.

Reference in the specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment.

Some portions of the detailed description herein are presented in terms of algorithms and symbolic representations of operations on data bits within a computer memory. These algorithmic descriptions and representations are the means used by those skilled in the computing arts to most effectively convey the substance of their work to others skilled in the art. An algorithm is here, and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the discussion herein, it is appreciated that throughout the description, discussions utilizing terms such as “processing” or “computing” or “calculating” or “determining” or “displaying” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Certain embodiments also relate to apparatus for performing the operations herein. This apparatus may be specially constructed for the required purposes, or it may comprise a general purpose computer selectively activated or reconfigured by a computer program stored in the computer. Such a computer program may be stored in a computer readable storage medium, such as, but is not limited to, any type of disk including floppy disks, optical disks, CD-ROMs, and magnetic-optical disks, read-only memories (ROMs), random access memories (RAMs) such as dynamic RAM (DRAM), EPROMs, EEPROMs, magnetic or optical cards, or any type of media suitable for storing electronic instructions, and coupled to a computer system bus.

The algorithms and displays presented herein are not inherently related to any particular computer or other apparatus. Various general purpose systems may be used with programs in accordance with the teachings herein, or it may prove convenient to construct more specialized apparatus to perform the required method steps. The required structure for a variety of these systems will appear from the description herein. In addition, certain embodiments are not described with reference to any particular programming language. It will be appreciated that a variety of programming languages may be used to implement the teachings of such embodiments as described herein.

Besides what is described herein, various modifications may be made to the disclosed embodiments and implementations thereof without departing from their scope. Therefore, the illustrations and examples herein should be construed in an illustrative, and not a restrictive sense. The scope of the invention should be measured solely by reference to the claims that follow.

1. A method of fabricating a pixel cell, the method comprising:
doping a substrate for the pixel cell with a first dopant through a backside of the substrate;
after the doping with the first dopant, thinning the substrate to form a front side of the substrate;
after the thinning the substrate:
doping the substrate with a second dopant through the front side of the substrate; and
forming a metal layer, wherein the front side of the substrate faces toward the metal layer.

2. The method of claim 1, further comprising bonding a carrier layer to the backside of the substrate after the doping with the first dopant.

3. The method of claim 2, wherein the thinning the substrate is performed while the carrier layer is bonded to the backside of the substrate.

4. The method of claim 1, wherein the first dopant includes an n-type dopant.

5. The method of claim 4, wherein the second dopant includes an n-type dopant.

6. The method of claim 1, wherein the doping with the first dopant is to form one or more pixel structures of a front side illumination pixel cell.

7. The method of claim 1, wherein the doping with the first dopant forms a first doped region and wherein the doping with the second dopant forms a second doped region adjoining the first doped region.

8. The method of claim 7, wherein a first pixel structure of the pixel cell comprises the first doped region and the second doped region.

9. The method of claim 8, wherein the first pixel structure includes one of a photodiode region, a diffusion well, and an isolation structure.

10. The method of claim 8, wherein a thickness of the substrate between the front side and the backside is at least three microns.

11. A pixel array comprising:
a first pixel cell including a doped region formed in a semiconductor substrate, wherein a dopant concentration profile for the doped region comprises:
a first portion including a first concentration gradient along a line extending between a backside of the substrate and a frontside of the substrate opposite the backside, wherein the first concentration gradient is according to a first log-normal curve; and
a second portion including a second concentration gradient along the line extending between the backside of the substrate and the frontside of the substrate, wherein the second concentration gradient is according to a second log-normal curve.

12. The pixel array of claim 11, wherein the dopant concentration profile further comprises:
a third portion is located between the first portion and the second portion, wherein the third portion including a concentration gradient which is not according to only the first log-normal curve and which is not according to only the second log-normal curve.

13. The pixel array of claim 12, wherein the concentration gradient of the third portion is according to a sum of curves which includes the first log-normal curve and the second log-normal curve.

14. The pixel array of claim 11, wherein the dopant concentration profile for the doped region includes two or more local dopant concentration maxima.

15. The pixel array of claim 14, wherein one of the two or more local maxima is substantially equal to a maxima of the first log-normal curve.

16. An image sensor device comprising:
a pixel array including:
a first pixel cell including a doped region formed in a semiconductor substrate, wherein a dopant concentration profile for the doped region comprises:
a first portion including a first concentration gradient along a line extending between a backside of the substrate and a frontside of the substrate opposite the backside, wherein the first concentration gradient is according to a first log-normal curve; and
a second portion including a second concentration gradient along the line extending between the backside of the substrate and the frontside of the substrate, wherein the second concentration gradient is according to a second log-normal curve; and
readout circuitry coupled to read out image data from the pixel array.

17. The image sensor device of claim 16, wherein the dopant concentration profile further comprises:
a third portion is located between the first portion and the second portion, wherein the third portion including a concentration gradient which is not according to only the first log-normal curve and which is not according to only the second log-normal curve.

18. The image sensor device of claim 17, wherein the concentration gradient of the third portion is according to a sum of curves which includes the first log-normal curve and the second log-normal curve.

19. The image sensor device of claim 16, wherein the dopant concentration profile for the doped region includes two or more local dopant concentration maxima.

20. The image sensor device of claim 19, wherein one of the two or more local maxima is substantially equal to a maxima of the first log-normal curve.
